(19) United States
(12) Patent Application Publication
(10) Pub. No.: US 2026/0164709 A1
(43) Pub. Date: Jun. 11, 2026

(54) SILICON CARBIDE PLANAR MOSFET WITH HYBRID LINEAR AND HEXAGONAL CHANNEL ARCHITECTURE

(71) Applicant: Renesas Electronics Corporation, Tokyo (JP)

(72) Inventors: Meng Chia LEE, Dallas, TX (US); Kijeong HAN, Morrisville, NC (US); Dilip Madhav RISBUD, San Jose, CA (US)

(73) Assignee: Renesas Electronics Corporation, Tokyo (JP)

(21) Appl. No.: 18/969,449

(22) Filed: Dec. 5, 2024

(51) Int. Cl. H10D 30/66; H10D 30/01; H10D 30/83; H10D 62/17; H10D 62/832

(52) U.S. Cl. CPC H10D 30/66; H10D 30/831; H10D 62/235; H10D 62/8325; H10D 30/025

(57) ABSTRACT

A semiconductor structure includes a silicon carbide semiconductor substrate of a first conductivity type having an upper and bottom surface. A drift region of the first conductivity type is located on the upper surface. Above the drift region, a channel region of a second conductivity type, opposite to the first conductivity type, is located featuring a hybrid configuration. The hybrid configuration includes a first channel segment of a first channel geometry located between and directly connected to two second channel segments of a second channel geometry. A source region of the first conductivity type is located adjacent to the channel region. A first doped semiconductor region of the second conductivity type, featuring a third geometry, is placed above the drift region and adjacent to the first channel segment. Finally, a gate electrode is located above the drift region via a gate oxide.

### BACKGROUND

The present disclosure generally relates to the field of semiconductor devices, and more particularly to planar metal-oxide-semiconductor field-effect transistors (MOSFETs).

The rapid advancement of power electronics has created a growing demand for high-performance semiconductor devices capable of operating at elevated voltages, temperatures, and frequencies. MOSFETs are integral components in modern power conversion and management systems, utilized in applications ranging from electric vehicles and renewable energy systems to industrial motor drives.

Among the various semiconductor materials, silicon carbide (SiC) has gained significant attention due to its superior properties, such as a wide bandgap, high thermal conductivity, and excellent electric field breakdown strength. These characteristics make SiC an ideal candidate for high-voltage and high-temperature applications, outperforming traditional silicon-based devices in terms of efficiency and thermal performance.

However, the design and fabrication of SiC MOSFETs come with unique challenges. Traditional planar MOSFET structures often suffer from issues related to spreading resistance. This can lead to increased power loss, reduced efficiency, decreased current handling, voltage drop, impaired switching performance and non-uniform current distribution. To address these limitations, innovative designs are necessary to improve the robustness and performance of planar SiC MOSFETs.

### SUMMARY

According to an embodiment of the present disclosure, a semiconductor structure includes a semiconductor substrate of a first conductivity type having an upper surface and a bottom surface. The semiconductor substrate includes a silicon carbide substrate. A drift region of the first conductivity type is located on the upper surface of the semiconductor substrate. A channel region of a second conductivity type, opposite to the first conductivity type, is located above the drift region. The channel region has a hybrid configuration including a first channel segment of a first channel geometry located between and directly connected to two second channel segments of a second channel geometry. A source region of the first conductivity type is adjacent to the channel region. A first doped semiconductor region of the second conductivity type is located above the drift region and adjacent to the first channel segment. The first doped semiconductor region includes a third geometry. Additionally, a gate electrode is located above the drift region via a gate oxide.

According to another embodiment of the present disclosure, a semiconductor structure includes a semiconductor substrate of a first conductivity type having an upper surface and a bottom surface. The semiconductor substrate includes a silicon carbide substrate. A drift region of the first conductivity type is located on the upper surface of the semiconductor substrate. A channel region of a second conductivity type, opposite to the first conductivity type, is located above the drift region. The channel region has a hybrid configuration including a first channel segment of a first channel geometry located between two second channel segments of a second channel geometry. A source region of the first conductivity type is adjacent to the channel region. A first doped semiconductor region of the second conductivity type is located above the drift region and adjacent to the first channel segment. The first doped semiconductor region includes a third geometry. Finally, a gate electrode is located above the drift region via a gate oxide.

According to yet another embodiment of the present disclosure, a semiconductor structure includes a semiconductor substrate of a first conductivity type having an upper surface and a bottom surface. The semiconductor substrate includes a silicon carbide substrate. A drift region of the first conductivity type is located on the upper surface of the semiconductor substrate. A channel region of a second conductivity type, opposite to the first conductivity type, is located above the drift region. The channel region has a hybrid configuration including a first channel segment of a first channel geometry located between two second channel segments of a second channel geometry. A source region of the first conductivity type is adjacent to the channel region. A first doped semiconductor region of the second conductivity type is located above the drift region. The first doped semiconductor region is laterally abutted by the first channel segment. The first doped semiconductor region includes a third geometry. Finally, a gate electrode is located above the drift region via a gate oxide.

### BRIEF DESCRIPTION OF THE DRAWINGS

The following detailed description, given by way of example and not intended to limit the embodiments described herein, will best be appreciated in conjunction with the accompanying drawings, in which:

FIG. 1 is a top-down view of a semiconductor structure illustrating components of a SiC planar MOSFET with hybrid channel architecture, according to an embodiment of the present disclosure;

FIG. 2 is a cross-sectional view of the semiconductor structure taken along line A-A′, according to an embodiment of the present disclosure;

FIG. 3 is a cross-sectional view of the semiconductor structure taken along line B-B′, according to an embodiment of the present disclosure;

FIG. 4 is a top-down view of a semiconductor structure illustrating another example of a SiC planar MOSFET with hybrid channel architecture, according to an embodiment of the present disclosure;

FIG. 5 is a top-down view of a semiconductor structure illustrating another example of a SiC planar MOSFET with hybrid channel architecture, according to an embodiment of the present disclosure; and

FIG. 6 is a flowchart depicting operational steps for the fabrication of a SiC planar MOSFET with hybrid channel architecture, according to an embodiment of the present disclosure.

The drawings are not necessarily to scale. The drawings are merely schematic representations, not intended to portray specific parameters of the embodiments in the present disclosure. The drawings are intended to depict typical embodiments of the present disclosure. In the drawings, like numbering represents like elements.

### DETAILED DESCRIPTION

Detailed embodiments of the claimed structures and methods are disclosed herein; however, it can be understood that the disclosed embodiments are merely illustrative of the claimed structures and methods that may be embodied in various forms. The claimed structures and methods may, however, be embodied in many different forms and should not be construed as limited to the exemplary embodiments set forth herein. In the description, details of various conventional features and techniques may be omitted to avoid unnecessarily obscuring the presented embodiments.

For purposes of the description hereinafter, terms such as “upper”, “lower”, “right”, “left”, “vertical”, “horizontal”, “top”, “bottom”, and derivatives thereof shall relate to the disclosed structures and methods, as oriented in the drawing figures. Terms such as “above”, “overlying”, “atop”, “on top”, “positioned on” or “positioned atop” mean that a first element, such as a first structure, is present on a second element, such as a second structure, wherein intervening elements, such as an interface structure may be present between the first element and the second element. The term “direct contact” means that a first element, such as a first structure, and a second element, such as a second structure, are connected without any intermediary conducting, insulating or semiconductor layers at the interface of the two elements.

In the interest of not obscuring the presentation of embodiments of the present disclosure, in the following detailed description, some processing steps or operations that may be ordinary in the art may have been combined together for presentation and for illustration purposes and in some instances may have not been described in detail. In other instances, some processing steps or operations that may be ordinary in the art may not be described at all. It should be understood that the following description is rather focused on the distinctive features or elements of various embodiments of the present disclosure.

In many silicon carbide (SiC) planar MOSFET designs, P+regions and their associated contacts are arranged periodically along the length of the device cell. This periodic placement can introduce spreading resistance, which negatively impacts the performance of the device by increasing the resistance that the current must overcome as it flows through the channel. The presence of the P+ regions not only contributes to the spreading resistance but also leads to a reduction in channel density for electron currents. This phenomenon, referred to as “channel density reduction,” results in diminished electron mobility and overall device efficiency. Furthermore, the linear nature of the channel in traditional planar MOSFET designs can exacerbate the effects of spreading resistance, as the current may encounter variations in resistance along its path.

Embodiments of the present disclosure provide a SiC planar MOSFET with a hybrid channel architecture and optimized placement of P+ regions that improves current flow and channel density. Specifically, the proposed SiC MOSFET with hybrid channel architecture introduces a hexagonal channel region with an additional horizontal or linear channel region positioned across the junction field-effect transistor (JFET) region that expands the JFET area, improving conductivity and current control. Additionally, the proposed SiC MOSFET with hybrid channel architecture can, among other benefits, reduce spreading resistance, lower channel resistance, and lower capacitance compared to conventional structures. These improvements lead to enhanced switching performance and overall efficiency, making the device well-suited for high-performance applications.

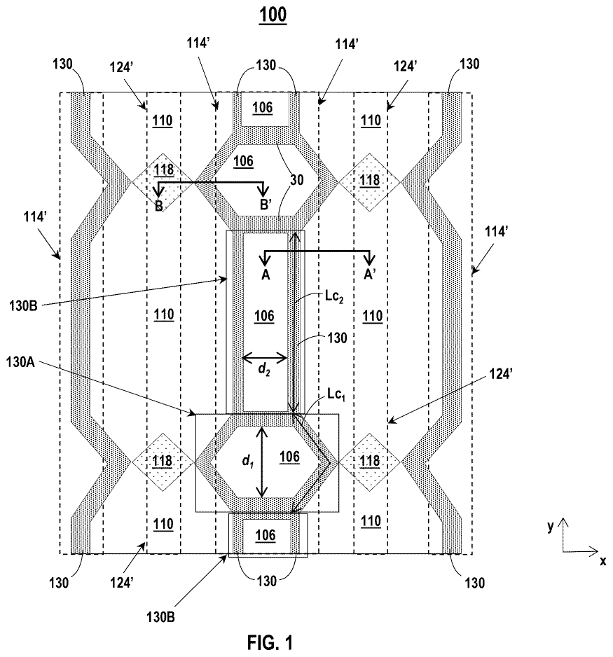

Embodiments by which the SiC planar MOSFET with hybrid channel architecture can be formed is described in detail below by referring to the accompanying drawings in FIGS. 1-6.

FIG. 1 is a top-down view of a semiconductor structure 100 illustrating components of a SiC planar MOSFET with hybrid channel architecture, according to an embodiment of the present disclosure. Semiconductor structure 100 includes source region 110 that adjoins outer sidewalls of respective channel regions 130. A centrally located junction field effect transistor (JFET) region 106 adjoins inner sidewalls of channel regions 130. In the depicted embodiment, channel regions 130 are arranged following a hybrid layout. The hybrid layout or configuration of channel regions 130 includes a first channel segment 130A featuring a first channel geometry and a second channel segment 130B featuring a second channel geometry. In an embodiment, the first channel segment 130A is located between two second channel segments 130B. The first channel segment 130A directly connects to each second channel segments 130B on opposite sides. It should be noted that the top-down view of FIG. 1 depicts only a portion of a single transistor cell. This transistor cell can be replicated multiple times in both the X and Y directions across the wafer to create a fully fabricated MOSFET device. As a result, some sections of the channel region 130, particularly the second channel segments 130B, are cut or not fully depicted in FIG. 1, since only a portion of the transistor cell is shown.

In the depicted embodiment, the first channel geometry of first channel segment 130A includes a hexagonal geometry, while each of the second channel segments 130B exhibits a linear geometry. The hexagonal geometry allows first channel segments 130A to be connected on opposite sides to the second channel segment 130B, while having two lateral protruding regions that extend towards first doped semiconductor regions 118. This arrangement can improve current distribution within semiconductor structure 100. The linear geometry of second channel segments 130B expands an area of the JFET region 106 further improving conductivity and current control. In the figure, projection lines 114′ and 124′ illustrate a location of a gate region (e.g., gate electrode 114) and an ohmic contact region (e.g., top metal layer 124), respectively. In an embodiment, first doped semiconductor regions 118 can be formed with a third geometry. The third geometry can be a quadrilateral geometry. In the example of FIG. 1, first doped semiconductor regions 118 are formed with a diamond-like shape that allows protruding lateral regions of the first doped semiconductor regions 118 to be in contact with protruding lateral regions of the first channel segment 130A for enhanced current flow.

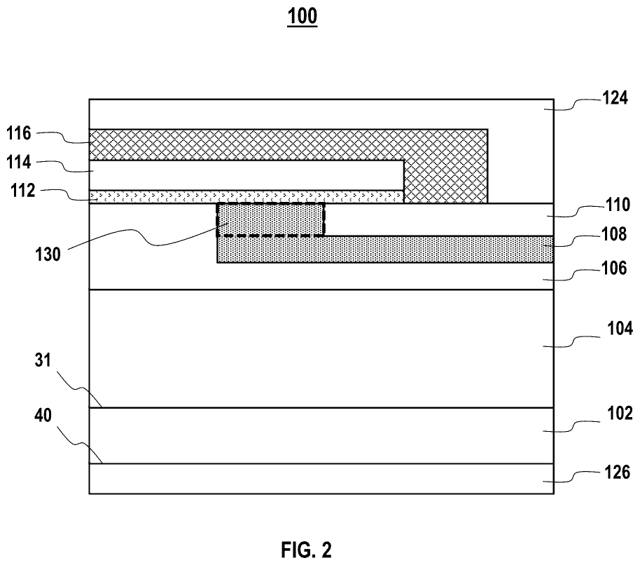

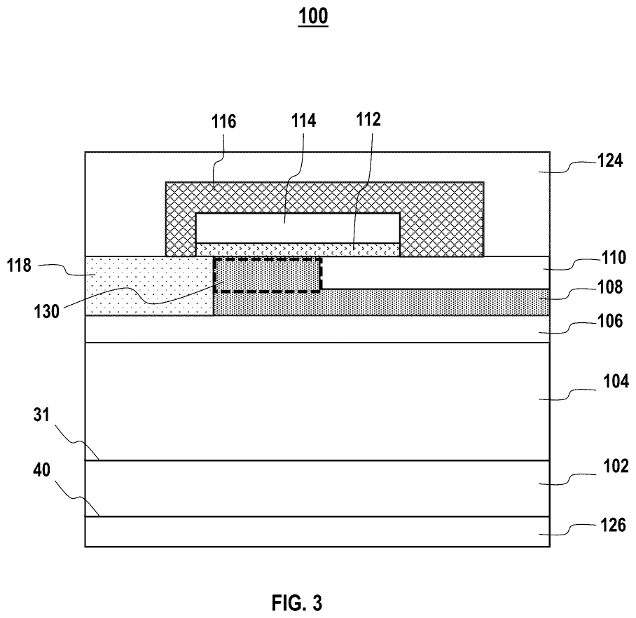

FIG. 2 is a cross-sectional view of the semiconductor structure 100 taken along line A-A′, while FIG. 3 is a cross-sectional view of the semiconductor structure 100 taken along line B-B′, as depicted in FIG. 1, according to an embodiment of the present disclosure.

With reference now to FIGS. 1-3 simultaneously, according to an embodiment, the semiconductor structure 100 includes a semiconductor substrate (hereinafter “substrate”) 102 of a first conductivity type made of silicon carbide (SiC). A thickness of the initial substrate 102 is approximately 350 μm. The substrate 102 can be grinded to approximately 100 μm during backside processing steps. The impurity concentration in the substrate 102 can vary between approximately 1×10¹⁸ cm⁻³ to approximately 1×10¹⁹ cm⁻³. The first conductivity type can be P-type or N-type.

It should be noted that substrate 102 serves as a drain region for the semiconductor structure 100, providing a pathway for current flow. While the drain region is integrated within the substrate 102, in some embodiments it can be engineered with distinct doping characteristics or other modifications to meet specific designs, enhance performance or manage thermal properties. Substrate 102 further includes an upper surface 31 and a bottom surface 40, as depicted in FIGS. 2-3.

A drift region 104 of the first conductivity type is formed on the upper surface 31 of the substrate 102. The drift region 104 is made of silicon carbide with an added impurity concentration that is lower than the impurity concentration of substrate 102. In general, drift region 104 can be formed by epitaxial growth by using the semiconductor substrate 102 as seed layer. Terms such as “epitaxial growth and/or deposition” and “epitaxially formed and/or grown” refer to the growth of a semiconductor material on a deposition surface of a semiconductor material, in which the semiconductor material being grown has the same or substantially similar crystalline characteristics as the semiconductor material of the deposition surface. In some embodiments, drift region 104 can be formed by chemical vapor deposition (CVD) of the semiconductor material (i.e., SiC).

A thickness of the drift region 104 is determined by the device voltage rating. For example, the thickness of the drift region 104 can be approximately 10 μm for 1.2 kV rated devices. The impurity concentration of the drift region 104 can be approximately 1×10¹⁶ cm⁻³ for 1.2 kV rated devices. However, the impurity concentration of the drift region 104 is not limited to this value and may be in a range of approximately 1×10¹⁴ cm⁻³ to approximately 1×10¹⁷ cm⁻³ depending on the device voltage rating.

The semiconductor structure 100 further JFET region 106, a base region 108 formed above the JFET region 106, a source region 110 formed above the base region 110, a gate oxide 112 formed above and in contact with JFET region 106, base region 108 and source region 110, a gate electrode 114 formed above the gate oxide 112, an interlevel dielectric layer 116 formed above the gate electrode, and a top metal layer 124 formed above the interlevel dielectric layer 116.

JFET region 106 is formed above and in contact with the drift region 104. In some instances, JFET region 106 can be formed with a higher donor doping of the first conductivity type that can vary between approximately 1×10¹⁵ cm⁻³ and approximately 1×10¹⁸ cm⁻³. A thickness of the JFET region 106 is approximately 0.1 μm to approximately 3.5 μm.

The base region 108 includes a doped semiconductor region of a second conductivity type formed above the JFET region 106. A thickness of the base region 108 is approximately 0.1 μm to approximately 1.0 μm. The impurity concentration of the base region 108 can vary between approximately 1×10¹⁹ cm⁻³ to approximately 1×10²¹ cm⁻³. The second conductivity type can be P-type or N-type. Generally, the second conductivity type is opposite to the first conductivity type. In an embodiment, a channel region 130 of the second conductivity type is formed within base region 108. Channel region 130 is disposed along JFET region 106 adjoining source region 110 and first doped semiconductor region 118. It can be understood that when a sufficiently high voltage is applied to gate electrode 114 relative to source region 110, a conduction channel forms in channel region(s) 130.

As depicted in the top-down view of FIG. 1, the channel region 130 includes a hybrid configuration consisting of a first channel segment 130A featuring the first channel geometry connected to second channel segments 130B featuring the second channel geometry. In one or more embodiments, each first channel segment 130A includes a first channel length Lc₁, while each second channel segment 130B includes a second channel length Lc₂. First channel length Lc₁ and second channel length Lc₂ are positioned between respective JFET region 106 and source region 110. In an example, first channel length Lc₁ can be of approximately 1 μm to approximately 10 μm, while second channel length Lc₂ can be of approximately 1 μm to approximately 100 μm. The hybrid configurating consisting of the first and second geometries increases the overall channel density. Specifically, vertices of the first (hexagonal) geometry form zig-zag patterns that extend towards the first doped semiconductor regions 118, effectively increasing the channel length compared to conventional linear designs.

In embodiments in which the first channel geometry is a hexagonal geometry, a distance d₁ between opposite sides of the first channel segment 130A can be of approximately 1 μm to approximately 100 μm. In embodiments in which the second channel geometry is a linear geometry, a distance d₂ between opposite parallel sides of the second channel segment 130B can be of approximately 0.1 μm to approximately 5 μm. In the depicted embodiment, transversal portions 30 form a bridge between lateral sections of the first channel segment 130A, effectively enclosing the JFET region 106 positioned within the first channel segment 130A. This configuration helps prevent premature electrical breakdown, ensuring reliable operation of the planar SiC MOSFET.

The source region 110 is formed above and in contact with the base region 108. A thickness of the source region 110 is approximately 0.1 μm to approximately 0.5 μm. Source region 110 may include a heavily-doped semiconductor layer of the first conductivity type. A dopant concentration of source region 110 can vary, for example, between 1×10¹⁹ cm⁻³ and 1×10²¹ cm⁻³.

In one or more embodiments, varying impurity or dopant concentrations across the different regions of semiconductor structure 100 can be attained through ion implantation or the diffusion of impurity ions or dopants. For example, in embodiments in which the first conductivity type is N-type and the second conductivity type is P-type, N-type dopants such as phosphorus (P) or arsenic (As) can be implanted into different regions of semiconductor structure 100 to form N-type doped semiconductor regions, while P-type dopants such as boron (B), aluminum (Al) or gallium (Ga) can be implanted into different regions of semiconductor structure 100 to form the P-type doped semiconductor regions.

With continued reference to FIGS. 1-3, first doped semiconductor region 118 is formed above and in contact with JFET region 106 and adjacent to base region 108, as depicted in the cross-sectional view of FIG. 3. The location of first doped semiconductor 118 can also be appreciated in the top-down view of semiconductor structure 100 shown in FIG. 1. First doped semiconductor region 118 includes a semiconductor region composed of a heavily doped silicon carbide layer of the second conductivity type. An ion implantation process can be conducted on the semiconductor structure 100 to form first doped semiconductor regions 118. First doped semiconductor regions 118 can be formed with an impurity concentration of the second conductivity type varying between approximately 1×10¹⁹ cm⁻³ and approximately 1×10²¹ cm⁻³. In embodiments in which the second conductivity type is P-type, first doped semiconductor regions 118 can be referred to as P+ regions.

A thickness of first doped semiconductor region 118 can vary between approximately 0.1 μm and approximately 3.5 μm. As illustrated in FIG. 1, the first doped semiconductor region 118 features a diamond-like shape. The diamond-like shape can promote a more uniform current distribution across the channel region 130, reduce localized current concentrations that can lead to increased resistance, and minimize spreading resistance by providing a larger contact area at the edges. It is important to note that the shape of the first doped semiconductor region 118 is not limited to the diamond shape shown in FIG. 1. In other embodiments, this region can take various shapes tailored to improve current distribution and overall device efficiency. For example, the first doped semiconductor region 118 could be designed as a quadrilateral (such as a rectangle or square), triangular, circular, or other configurations.

With continued reference to FIGS. 1-3, gate oxide 112 can be formed above first doped semiconductor region 118, base region 108 and source region 110 using various types of deposition processes. The gate oxide 112 can electrically separate a subsequently formed gate electrode from active areas of the semiconductor structure 100. In one or more embodiments, gate oxide 112 can be formed by conformal deposition of a gate insulating film. Non-limiting examples of gate insulating films to form gate oxide 112 can include silicon dioxide (SiO₂), silicon nitride (Si₃N₄), aluminum oxide (Al₂O₃), lanthanum oxide (La₂O₃), zirconium dioxide (ZrO₂), tantalum oxide (Ta₂O₅), hafnium oxide (HfO₂) and the like. In an exemplary embodiment, a thickness of the gate oxide 112 can vary between approximately 10 nm to approximately 100 nm.

The process of forming gate electrode 114 usually includes depositing a conductive material, such as polysilicon, above the gate electrode 112. The gate electrode 114 and gate oxide 112 provide a gate structure for the semiconductor structure 100. After forming the gate electrode 114, interlevel dielectric layer 116 can be formed to fill voids and electrically isolate active regions within the semiconductor structure 100. The interlevel dielectric layer 116 is disposed above the gate electrode 114. More particularly, the interlevel dielectric layer 116, as depicted in FIGS. 2 and 3, covers an upper surface and opposite sidewalls of gate electrode 114, opposite sidewalls of gate oxide 112, and partially covers an upper surface of first doped semiconductor region 118 and source region 110. In one or more embodiments, the interlevel dielectric layer 116 can be formed by, for example, conformal deposition (e.g., CVD) of a dielectric material such as silicon oxide, silicon nitride, and the like. In one or more embodiments, a patterning process can be conducted on the interlevel dielectric layer 116 to achieved the shape shown in the figures.

In an embodiment, a top metal layer 124 is deposited above the interlevel dielectric layer 116 and above exposed portions of source region 110 and first doped semiconductor region 118, as shown in FIG. 3. The top metal layer 124 provides a source terminal or source electrode that electrically contacts source region 110 and first doped semiconductor region 118.

A bottom metal layer 126 can be formed on the bottom surface 40 of the substrate 102. The bottom metal layer 126 serves as a drain terminal or drain electrode that provides electrical (ohmic) contact with substrate 102.

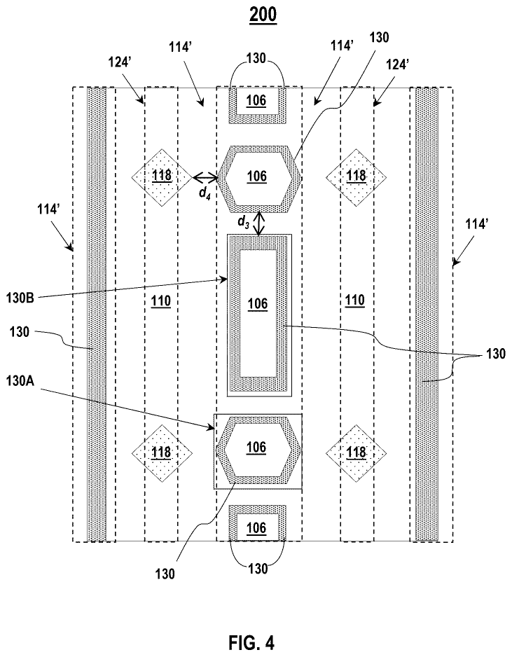

FIG. 4 is a top-down view of a semiconductor structure 200 illustrating another example of a SiC planar MOSFET with hybrid channel architecture, according to an embodiment of the present disclosure. In this embodiment, first channel segment 130A and second channel segment 130B are separated by a distance d₃. In an embodiment, the distance d₃ between first channel segment 130A and second channel segment 130B can be of approximately 0.05 μm to approximately 5 μm. Unlike the connected hybrid channel depicted in FIG. 1, the first and second channel segments 130A, 130B are distinct and not connected.

As in semiconductor structure 100 of FIG. 1, first doped semiconductor regions 118 are located adjacent to the first channel segment 130A; however, in this embodiment, first doped semiconductor regions 118 are separated from the first channel segment 130A by a distance d₄. In an embodiment, the distance d₄ between first doped semiconductor regions 118 and first channel segment 130A can be of approximately 0.05 μm to approximately 5 μm. The first geometry of the first channel segment 130A includes a hexagonal shape, while the second geometry of the second channel segment 130B includes a linear geometry. In this embodiment, the third geometry of the first doped semiconductor regions 118 adjacent to the first channel segment 130A includes a quadrilateral geometry. Specifically, the third geometry of the first doped semiconductor regions 118 includes a diamond-like shape.

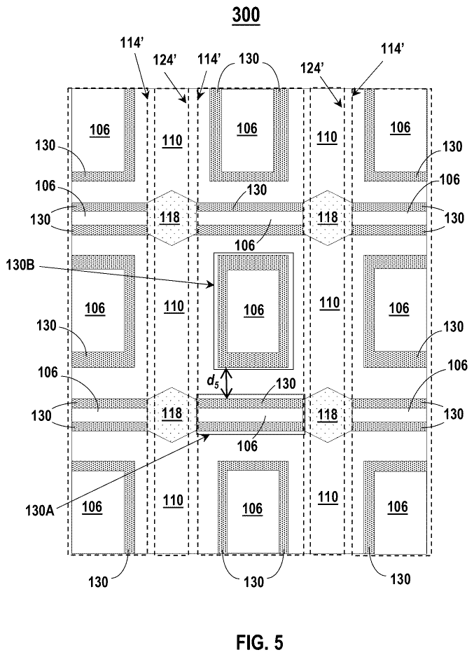

FIG. 5 is a top-down view of a semiconductor structure 300 illustrating another example of a SiC planar MOSFET with hybrid channel architecture, according to an embodiment of the present disclosure. In this embodiment, first channel segment 130A and second channel segment 130B are separated by a distance d₅. In an embodiment, the distance d₅ between first channel segment 130A and second channel segment 130B can be of approximately 0.05 μm to approximately 0.5 μm. Unlike the connected hybrid channel depicted in FIG. 1, the first and second channel segments 130A, 130B are distinct and not connected.

In this embodiment, first doped semiconductor regions 118 are located adjacent and in contact with opposite sides of the first channel segment 130A; however, in this embodiment, first doped semiconductor regions 118 is formed with a third geometry featuring a hexagonal geometry. As depicted in the figure, first doped semiconductor regions 118 are connected on opposite sides with first channel segment 130A with two opposite protruding regions extending towards respective source region 110. In this embodiment, the first geometry of the first channel segment 130A includes a linear geometry, while the second geometry of the second channel segment 130B includes a quadrilateral geometry.

The embodiments depicted in FIG. 4 and FIG. 5 offer distinct configurations for hybrid channel architecture that can enhance channel density. These designs create new pathways for efficient current flow, reducing spreading resistance and ultimately improving overall device performance.

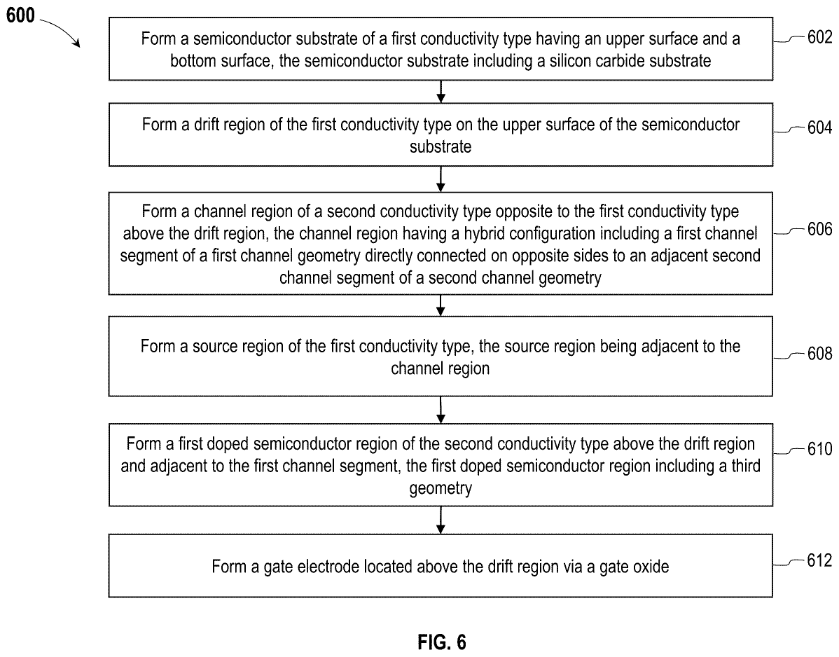

FIG. 6 is a flowchart 600 depicting operational steps for the fabrication of the semiconductor structure 100, according to an embodiment of the present disclosure.

The process starts at step 602 by forming a semiconductor substrate of a first conductivity type. The semiconductor substrate has an upper surface and a bottom surface. The semiconductor substrate is a silicon carbide substrate;

The process continues at step 604 by forming a drift region of the first conductivity type on the upper surface of the semiconductor substrate. At step 606, a channel region of a second conductivity type, opposite to the first conductivity type, is formed above the drift region. The channel region has a hybrid configuration including a first channel segment of a first channel geometry directly connected on opposite sides to an adjacent second channel segment of a second channel geometry. At step 608, a source region of the first conductivity type is formed adjacent to the channel region.

The process continues at step 610 by forming a first doped semiconductor region of the second conductivity type above the drift region and adjacent to the first channel segment. The first doped semiconductor region includes a third geometry. At step 612, a gate electrode is formed above the drift region via a gate oxide.

### EXAMPLES

Example 1. A method of forming a semiconductor structure, comprising:
forming a semiconductor substrate of a first conductivity type, the semiconductor substrate having an upper surface and a bottom surface, the semiconductor substrate including a silicon carbide substrate;
forming a drift region of the first conductivity type on the upper surface of the semiconductor substrate;
forming a channel region of a second conductivity type opposite to the first conductivity type above the drift region, the channel region having a hybrid configuration including a first channel segment of a first channel geometry directly connected on opposite sides to a second channel segment of a second channel geometry;
forming a source region of the first conductivity type adjacent to the channel region;
forming a first doped semiconductor region of the second conductivity type above the drift region and adjacent to the first channel segment, the first doped semiconductor region including a third geometry; and
forming a gate electrode above the drift region via a gate oxide.

Example 2. The method according to Example 1, wherein the first channel geometry of the first channel segment includes a hexagonal geometry.

Example 3. The method according to Example 1, wherein the second channel geometry of the second channel segment includes a linear geometry.

Example 4. The method according to Example 1, wherein the third geometry of the first doped semiconductor region includes a quadrilateral geometry.

Example 5. The method according to Example 1, wherein the first channel segment includes a first channel length adjoining the source region, and the first channel length is more than 1 μm and less than 10 μm.

Example 6. The method according to Example 1, wherein the second channel segment includes a second channel length adjoining the source region, and the second channel length is more than 1 μm and less than 100 μm.

Example 7. The method according to Example 1, wherein an impurity concentration of the first doped semiconductor region is more than 1×10¹⁹ cm⁻³ and less than 1×10²¹ cm⁻³.

Example 8. The method according to Example 1, further comprising:
forming a JFET region above the drift region;
forming a top metal layer above and electrically connected to the source region and first semiconductor region; and
forming a bottom metal layer located on the bottom surface of the semiconductor substrate.

Example 9. A method of forming a semiconductor structure, comprising:
forming a semiconductor substrate of a first conductivity type, the semiconductor substrate having an upper surface and a bottom surface, the semiconductor substrate including a silicon carbide substrate;
forming a drift region of the first conductivity type on the upper surface of the semiconductor substrate;
forming a channel region of a second conductivity type opposite to the first conductivity type above the drift region, the channel region having a hybrid configuration including a first channel segment of a first channel geometry positioned between two second channel segments of a second channel geometry;
forming a source region of the first conductivity type adjacent to the channel region;
forming a first doped semiconductor region of the second conductivity type above the drift region and adjacent to the first channel segment, the first doped semiconductor region including a third geometry; and
forming a gate electrode above the drift region via a gate oxide.

Example 10. The method according to Example 9, wherein the first channel geometry of the first channel segment includes a hexagonal geometry.

Example 11. The method according to Example 9, wherein the second channel geometry of each of the two second channel segments includes a linear geometry.

Example 12. The method according to Example 9, wherein the third geometry of the first doped semiconductor region includes a quadrilateral geometry.

Example 13. The method according to Example 9, wherein the first channel segment includes a first channel length adjoining the source region, and the first channel length is more than 1 μm and less than 10 μm.

Example 14. The method according to Example 9, wherein each of the second channel segments includes a second channel length adjoining the source region, and the second channel length is more than 1 μm and less than 100 μm.

Example 15. The method according to Example 9, wherein a distance between the first channel segment and each of the second channel segments is more than 0.05 μm and less than 5 μm.

Example 16. The method according to Example 9, further comprising:
forming a JFET region above the drift region;
forming a top metal layer above and electrically connected to the source region and first semiconductor region; and
forming a bottom metal layer on the bottom surface of the semiconductor substrate.

Example 17. A method of forming a semiconductor structure, comprising:
forming a semiconductor substrate of a first conductivity type, the semiconductor substrate having an upper surface and a bottom surface, the semiconductor substrate including a silicon carbide substrate;
forming a drift region of the first conductivity type on the upper surface of the semiconductor substrate;
forming a channel region of a second conductivity type opposite to the first conductivity type above the drift region, the channel region having a hybrid configuration including a first channel segment of a first channel geometry positioned between two second channel segments of a second channel geometry;
forming a source region of the first conductivity type adjacent to the channel region;
forming a first doped semiconductor region of the second conductivity type above the drift region, the first doped semiconductor region being laterally abutted by the first channel segment, the first doped semiconductor region including a third geometry; and
forming a gate electrode above the drift region via a gate oxide.

Example 18. The method according to Example 17, wherein the first channel geometry of the first channel segment includes a linear geometry.

Example 19. The method according to Example 17, wherein the second channel geometry of each of the two second channel segments includes a quadrilateral geometry.

Example 20. The method according to Example 17, wherein the third geometry of the first doped semiconductor region includes a hexagonal geometry.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. “Optional” or “optionally” means that the subsequently described event or circumstance may or may not occur, and that the description includes instances where the event occurs and instances where it does not.

Spatially relative terms, such as “inner,” “outer,” “beneath,” “below,” “lower,” “above,” “upper,” “top,” “bottom,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” may encompass both an orientation of above and below. The device may be otherwise oriented (rotated 90 degrees or at other orientations) and the spatially relative descriptors used herein interpreted accordingly.

Approximating language, as used herein throughout the specification and claims, may be applied to modify any quantitative representation that could permissibly vary without resulting in a change in the basic function to which it is related. Accordingly, a value modified by a term or terms, such as “about”, “approximately” and “substantially”, are not to be limited to the precise value specified. In at least some instances, the approximating language may correspond to the precision of an instrument for measuring the value. Here and throughout the specification and claims, range limitations may be combined and/or interchanged, such ranges are identified and include all the sub-ranges contained therein unless context or language indicates otherwise. “Approximately” as applied to a particular value of a range applies to both values, and unless otherwise dependent on the precision of the instrument measuring the value, may indicate +/−10% of the stated value(s).

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor structure comprising:
a semiconductor substrate of a first conductivity type having an upper surface and a bottom surface, the semiconductor substrate including a silicon carbide substrate;
a drift region of the first conductivity type located on the upper surface of the semiconductor substrate;
a channel region of a second conductivity type opposite to the first conductivity type located above the drift region, the channel region having a hybrid configuration including a first channel segment of a first channel geometry located between and directly connected to two second channel segments of a second channel geometry;
a source region of the first conductivity type adjacent to the channel region;
a first doped semiconductor region of the second conductivity type located above the drift region and adjacent to the first channel segment, the first doped semiconductor region including a third geometry; and
a gate electrode located above the drift region via a gate oxide.

2. The semiconductor structure according to claim 1, wherein the first channel geometry of the first channel segment includes a hexagonal geometry.

3. The semiconductor structure according to claim 1, wherein the second channel geometry of each of the two second channel segments includes a linear geometry.

4. The semiconductor structure according to claim 1, wherein the third geometry of the first doped semiconductor region includes a quadrilateral geometry.

5. The semiconductor structure according to claim 1, wherein the first channel segment includes a first channel length adjoining the source region, and the first channel length is more than 1 μm and less than 10 μm.

6. The semiconductor structure according to claim 1, wherein each of the two second channel segments includes a second channel length adjoining the source region, and the second channel length is more than 1 μm and less than 100 μm.

7. The semiconductor structure according to claim 1, wherein an impurity concentration of the first doped semiconductor region is more than 1×10¹⁹ cm⁻³ and less than 1×10²¹ cm⁻³.

8. The semiconductor structure according to claim 1, further comprising:
a JFET region located above the drift region;
a top metal layer above and electrically connected to the source region and first semiconductor region; and
a bottom metal layer located on the bottom surface of the semiconductor substrate.

9. A semiconductor structure comprising:
a semiconductor substrate of a first conductivity type having an upper surface and a bottom surface, the semiconductor substrate including a silicon carbide substrate;
a drift region of the first conductivity type located on the upper surface of the semiconductor substrate;
a channel region of a second conductivity type opposite to the first conductivity type located above the drift region, the channel region having a hybrid configuration including a first channel segment of a first channel geometry located between two second channel segments of a second channel geometry;
a source region of the first conductivity type adjacent to the channel region;
a first doped semiconductor region of the second conductivity type located above the drift region and adjacent to the first channel segment, the first doped semiconductor region including a third geometry; and
a gate electrode located above the drift region via a gate oxide.

10. The semiconductor structure according to claim 9, wherein the first channel geometry of the first channel segment includes a hexagonal geometry.

11. The semiconductor structure according to claim 9, wherein the second channel geometry of each of the two second channel segments includes a linear geometry.

12. The semiconductor structure according to claim 9, wherein the third geometry of the first doped semiconductor region includes a quadrilateral geometry.

13. The semiconductor structure according to claim 9, wherein the first channel segment includes a first channel length adjoining the source region, and the first channel length is more than 1 μm and less than 10 μm.

14. The semiconductor structure according to claim 9, wherein each of the two second channel segments includes a second channel length adjoining the source region, and the second channel length is more than 1 μm and less than 100 μm.

15. The semiconductor structure according to claim 9, wherein a distance between the first channel segment and each of the two second channel segments is more than 0.05 μm and less than 5 μm.

16. The semiconductor structure according to claim 9, further comprising:
a JFET region located above the drift region;
a top metal layer above and electrically connected to the source region and first semiconductor region; and
a bottom metal layer located on the bottom surface of the semiconductor substrate.

17. A semiconductor structure comprising:
a semiconductor substrate of a first conductivity type having an upper surface and a bottom surface, the semiconductor substrate including a silicon carbide substrate;
a drift region of the first conductivity type located on the upper surface of the semiconductor substrate;
a channel region of a second conductivity type opposite to the first conductivity type located above the drift region, the channel region having a hybrid configuration including a first channel segment of a first channel geometry located between two second channel segments of a second channel geometry;
a source region of the first conductivity type adjacent to the channel region;
a first doped semiconductor region of the second conductivity type located above the drift region, the first doped semiconductor region being laterally abutted by the first channel segment, the first doped semiconductor region including a third geometry; and
a gate electrode located above the drift region via a gate oxide.

18. The semiconductor structure according to claim 17, wherein the first channel geometry of the first channel segment includes a linear geometry.

19. The semiconductor structure according to claim 17, wherein the second channel geometry of each of the two second channel segments includes a quadrilateral geometry.

20. The semiconductor structure according to claim 17, wherein the third geometry of the first doped semiconductor region includes a hexagonal geometry.
